(19) United States
(12) Patent Application Publication
(10) Pub. No.: US 2026/0123234 A1
(43) Pub. Date: Apr. 30, 2026

(54) DISPLAY PANEL, METHOD OF MANUFACTURING DISPLAY PANEL, AND DISPLAY APPARATUS

(71) Applicant: HKC CORPORATION LIMITED, SHENZHEN (CN)

(72) Inventors: Dongmei WEI, SHENZHEN (CN); Lidan YE, SHENZHEN (CN)

(73) Assignee: HKC CORPORATION LIMITED, SHENZHEN (CN)

(21) Appl. No.: 19/369,376

(22) Filed: Oct. 27, 2025

(30) Foreign Application Priority Data
Oct. 31, 2024 (CN) 202411548889.7

(51) Int. Cl. H10K 59/80; H10K 59/12

(52) U.S. Cl. CPC H10K 59/80515; H10K 59/1201

(57) ABSTRACT

A display panel includes: a silicon-based driver substrate and a light emitting carrier board. The light emitting carrier board includes: a glass substrate defining multiple anode through holes, a plurality of sub-pixels of different colors, a plurality of anode leads, a plurality of insulating layers. Each sub-pixel is arranged corresponding to one anode through hole. The anode leads are arranged in one-to-one correspondence with the sub-pixels. The anode leads are arranged in the anode through holes to connect anodes of the sub-pixels to the silicon-based driver substrate. The insulating layers are arranged on a side of the anodes away from the glass substrate and cover the anode leads and expose the anodes. Two anode leads corresponding to every adjacent two sub-pixels of a portion of the plurality of sub-pixels share one anode through hole and are insulated from each other by the insulating layer.

### CROSS REFERENCE TO RELATED APPLICATIONS

The present application claims the priority of the Chinese patent application No. 202411548889.7, filed on Oct. 31, 2024, contents of which are incorporated herein by its entireties.

### TECHNICAL FIELD

Embodiments of the present disclosure relate to the technical field of displaying, and more specifically, to a display panel, a method of manufacturing the display panel, and a display apparatus.

### BACKGROUND

An organic light-emitting diode (OLED) display apparatus is a device that takes currents to drive an organic semiconductor material to generate reversible color changes to display graphics. The OLED display apparatus is ultra-light in weight; ultra-thin; has high brightness, a large viewing angle, a low voltage, low power consumption, fast response, high definition; and is shock-resistant, bendable, low costly; and can be produced from simple processes, using less raw materials, having high luminous efficiency and a wide temperature range. Therefore, the OLED displaying technology is considered as a most promising new generation displaying technology.

In the art, the number of sub-pixels is the same as the number of anode through holes, and each sub-pixel needs to be connected to an anode and a circuit that drives the anode through the anode hole. In this way, a large number of through holes need to be defined in an OLED substrate, rigidity of the substrate may be destroyed, a risk of substrate breakage in subsequent production processes may be increased.

### SUMMARY

The present disclosure provides a display panel, a method of manufacturing the display panel, and a display apparatus, so as to reduce the risk of substrate breakage.

In a first aspect, the present disclosure provides a display panel, including:
a silicon-based driver substrate;
a light emitting carrier board, bonded and connected to the silicon-based driver substrate; where the light emitting carrier board includes:
a glass substrate, defining a plurality of anode through holes;
a plurality of sub-pixels of different colors, arranged on a surface of the glass substrate away from the silicon-based driver substrate; where each of the plurality of sub-pixels is arranged corresponding to a respective one of the plurality of anode through holes;
a plurality of anode leads, arranged in one-to-one correspondence with the plurality of sub-pixels; where the plurality of anode leads are arranged in the plurality of anode through holes to connect anodes of the plurality of sub-pixels to the silicon-based driver substrate;
a plurality of insulating layers, arranged on a side of the anodes away from the glass substrate and covering the plurality of anode leads and exposing the anodes.

Two anode leads of the plurality of anode leads corresponding to every adjacent two sub-pixels of a portion of the plurality of sub-pixels share a respective one of the plurality of anode through holes and are insulated from each other by a respective one of the plurality of insulating layers.
includes In a second aspect, the present disclosure provides a display apparatus, including a motherboard and the display panel as described in the above.

In a third aspect, the present disclosure provides a method of manufacturing the display panel as described in the above. The method includes:
providing the silicon-based driver substrate;
defining the plurality of anode through holes in the glass substrate;
preparing the plurality of sub-pixels of different colors, the plurality of anode leads and the plurality of insulating layers on the glass substrate to form the light emitting carrier board; where each of the plurality of sub-pixels is arranged corresponding to the respective one of the plurality of anode through holes; the plurality of anode leads are arranged in one-to-one correspondence with the plurality of sub-pixels; the plurality of anode leads are arranged in the plurality of anode through holes; the plurality of insulating layers are arranged on the side of the anodes away from the glass substrate and cover the plurality of anode leads and expose the anodes; where two anode leads of the plurality of anode leads corresponding to every adjacent two sub-pixels of the portion of the plurality of sub-pixels share the respective one of the plurality of anode through holes and are insulated from each other by the respective one of the plurality of insulating layers;
bonding the light emitting carrier board to the silicon-based driver substrate.

### BRIEF DESCRIPTION OF THE DRAWINGS

To more clearly illustrate technical solutions in the embodiments of the present disclosure or the related art, the accompanying drawings needed for describing the embodiments of the present disclosure or the related art will be briefly introduced in the following. Obviously, the drawings in the following description are only some embodiments of the present disclosure, and any ordinary skilled person in the art may obtain other drawings based on these drawings without creative work.

FIG. 1 is a structural schematic view of a display panel in the art.

FIG. 2 is a structural schematic view of a display panel according to a first embodiment of the present disclosure.

FIG. 3 is a cross-sectional view of the display panel shown in FIG. 2, taken along a line E-E.

FIG. 4 is a structural schematic view of the display panel according to a second embodiment of the present disclosure.

FIG. 5 is a structural schematic view of the display panel according to a third embodiment of the present disclosure.

FIG. 6 is a structural schematic view of the display panel according to a fourth embodiment of the present disclosure.

FIG. 7 is a structural schematic view of the display panel according to a fifth embodiment of the present disclosure.

FIG. 8 is a structural schematic view of the display panel according to a sixth embodiment of the present disclosure.

FIG. 9 is a flow chart of a method of manufacturing the display panel according to an embodiment of the present disclosure.

FIG. 10 is a structural schematic view of a structure corresponding to the operation S100 of the method shown in FIG. 9.

FIG. 11 is a structural schematic view of a structure corresponding to the operation S200 of the method shown in FIG. 9.

FIG. 12 is a flow chart of the operation S300 of the method shown in FIG. 9.

FIG. 13 is a structural schematic view of structures corresponding to operations S301 to S305 of the operation shown in FIG. 12.

FIG. 14 is a structural schematic view of a structure corresponding to the operation S306 of the operation shown in FIG. 12.

FIG. 15 is a structural schematic view of a structure corresponding to the operation S400 of the method shown in FIG. 9.

FIG. 16 is a structural schematic view of a display apparatus according to an embodiment of the present disclosure.

### REFERENCE NUMERALS IN THE DRAWINGS

100, display panel; 10, light emitting carrier board; 11, glass substrate; 111, anode through hole; 12, sub-pixel; 121, anode; 122, light emitting layer; 123, cathode; R, red sub-pixel; G, green sub-pixel; B, blue sub-pixel; 124, sub-pixel column; 125, pixel group; 126, end sub-pixel; 120, pixel unit; 12A, first pixel row; 12B, second pixel row; 13, anode lead; 13A, first anode lead; 13B, second anode lead; 14, insulating layer; 141, first insulating layer; 142, second insulating layer; 140, pixel opening; 15, encapsulation layer; 16, isolation structure; 171, first conductive layer; 172, second conductive layer; 181, first insulating material layer; 182, second insulating material layer; 20, silicon-based driver substrate; 21, silicon substrate; 22, driver circuit layer; 23, protection layer; 24, anode driver electrode; D1, first direction; D2, second direction; 200, motherboard; 300, display apparatus.

### DETAILED DESCRIPTIONS

Technical solutions of the present disclosure will be described in detail by referring to the accompanying drawings.

In the following description, specific details such as particular system structures, interfaces, techniques, and the like are provided for the purpose of illustration and not for limitation, in order to provide a thorough understanding of the present disclosure.

The technical solutions in the embodiments of the present disclosure will be clearly and completely described below by referring to the accompanying drawings in the embodiments of the present disclosure. Apparently, the described embodiments are only a part of, not all of, the embodiments of the present disclosure. All other embodiments, which are obtained by any ordinary skilled person in the art based on the embodiments in the present disclosure without making creative work, shall fall within the scope of the present disclosure.

Terms “first”, “second”, and “third” in the present disclosure are used for descriptive purposes only and are not to indicate or imply relative importance or implicitly specifying the number of technical features. Therefore, a feature defined with “first”, “second”, “third” may include at least one such feature, either explicitly or implicitly. In the description of the present disclosure, “a plurality of” means at least two, such as two, three, and so on, unless otherwise expressly and specifically limited. All directional indications (such as up, down, left, right, front, rear . . . ) in the embodiments of the present disclosure are only used to explain a relative positional relationship and movement between components at a particular attitude (the attitude as shown in the accompanying drawings). The directional indication may be changed accordingly when the particular attitude is changed. Furthermore, terms “include” and “have” and any variations thereof are intended to cover non-exclusive inclusion. For example, a process, a method, a system, a product or an apparatus including a series of steps or units is not limited to the listed steps or units, but may further include steps or units that are not listed or steps or units that are inherently included in the process, the method, the system, the product or the apparatus.

Reference to “embodiments” herein means that particular features, structures, or characteristics described in an embodiment may be included in at least one embodiment of the present disclosure. The phrase at various sections in the specification does not necessarily refer to one same embodiment, nor separate or alternative embodiments that are mutually exclusive of other embodiments. Any ordinary skilled person in the art shall understand that, both explicitly and implicitly, the embodiments described herein may be combined with other embodiments.

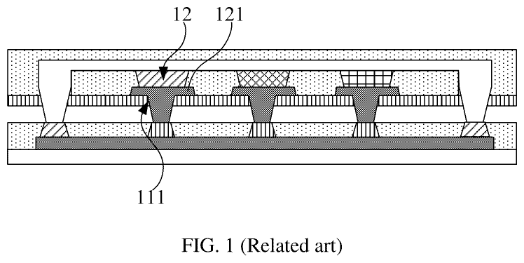

As shown in FIG. 1, FIG. 1 is a structural schematic view of a display panel in the art.

In the art, the number of sub-pixels 12 is the same as the number of anode through holes 111. An anode 121 of each sub-pixel 12 and a circuit driving the anode 121 are electrically connected to each other through the anode through hole 111. As the number of anode through holes 111 is large, a large number of through holes need to be defined in one substrate. Therefore, rigidity of the substrate may be reduced, and a risk of substrate breakage in subsequent production processes may be increased.

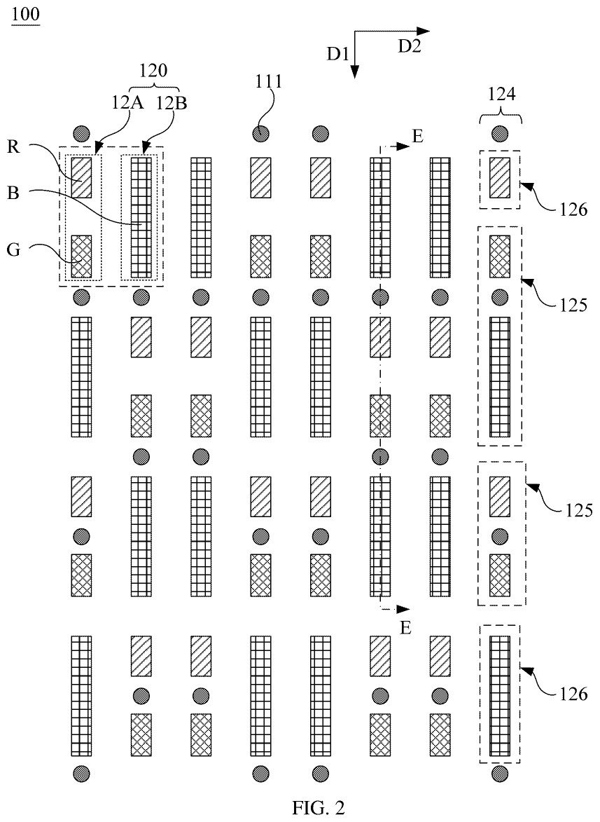

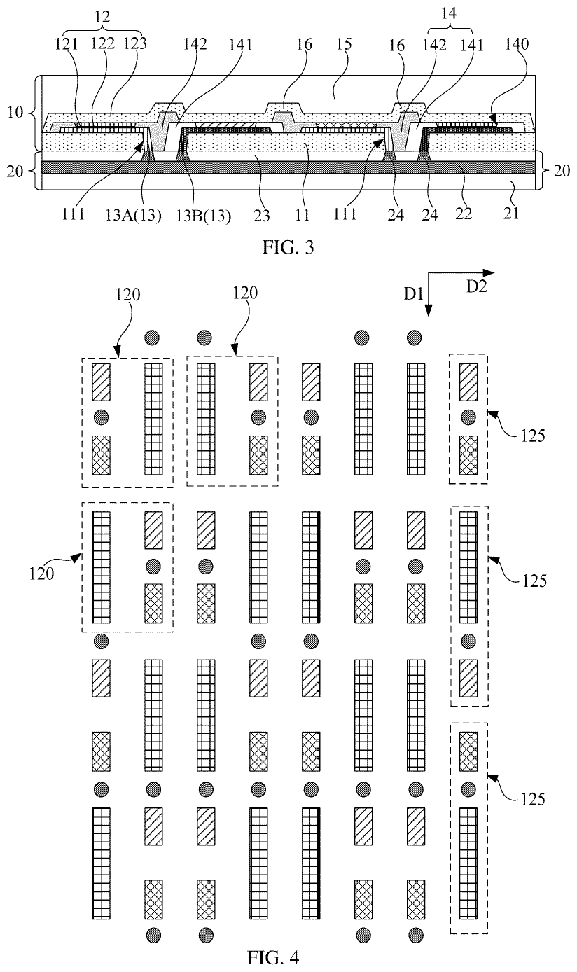

As shown in FIGS. 2 and 3, FIG. 2 is a structural schematic view of a display panel according to a first embodiment of the present disclosure; and FIG. 3 is a cross-sectional view of the display panel shown in FIG. 2, taken along a line E-E.

In order to solve the above technical problem, the present disclosure provides a display panel 100. The display panel 100 includes a silicon-based driver substrate 20 and a light emitting carrier board 10. The light emitting carrier board 10 may be bonded to the silicon-based driver substrate 20. The light emitting carrier board 10 may include a glass substrate 11, a plurality of sub-pixels 12 in different colors, a plurality of anode leads 13, and a plurality of insulating layers 14. The glass substrate 11 defines a plurality of anode through hole 111. The plurality of sub-pixels 12 in the different colors are arranged on a surface of the glass substrate 11 away from the silicon-based driver substrate 20. Each of the plurality of sub-pixels 12 is arranged corresponding to a respective one of the plurality of anode through holes 111. The plurality of anode leads 13 are arranged in one-to-one correspondence with the plurality of sub-pixels 12. The plurality of anode leads 13 are received in the plurality of anode through holes 111 to connect anodes 121 of the plurality of sub-pixels 12 to the silicon-based driver substrate 20. The plurality of insulating layers 14 are arranged on a side of the anodes 121 away from the glass substrate 11, and cover the plurality of anode leads 13 and expose the anodes 121. Two anode leads 13 corresponding to every adjacent two sub-pixels 12 of a portion of the plurality of sub-pixels 12 share one anode through hole 111 of the plurality of anode through holes 111 and are insulated from each other by a respective one of the plurality of insulating layers 14.

In the present disclosure, since every adjacent two sub-pixels 12 of a portion of the plurality of sub-pixels 12 share one anode through hole 111, the number of through holes defined in the glass substrate 11 may be reduced, and the risk of breakage of the glass substrate 11 during subsequent production processes may be reduced.

The silicon-based driver substrate 20 may include a silicon substrate 21 and a driver circuit layer 22. The driver circuit layer 22 may be arranged on a side of the silicon substrate 21 near the light emitting carrier board 10.

The silicon substrate 21 may refer to a substrate plate based on a monocrystalline silicon material.

The driver circuit layer 22 may include an active drive circuit (not shown) integrated on the silicon substrate 21 using a complementary metal-oxide-semiconductor (CMOS) process.

The silicon-based driver substrate 20 and the light emitting carrier board 10 may be prepared separately from each other, such that a production efficiency may be improved, and an effect, caused by an evaporation process, on the silicon-based driver substrate 20 may be avoided, a loss of the silicon-based driver substrate 20 may be reduced. That is, from a process perspective, separate preparation of the silicon-based driver substrate 20 and the light emitting carrier board 10 may improve a product yield and reduce production costs.

The glass substrate 11 may further define a cathode through hole (not shown), spaced apart from the plurality of anode through holes 111. A cathode 123 of each sub-pixel 12 may be electrically connected to the silicon-based driver substrate 20 through the cathode through hole. Each of the plurality of anode through holes 111 and the cathode through hole penetrate the glass substrate 11. A conductive material may be arranged in the cathode through hole, such that the conductive material in the cathode through hole may electrically connect the cathode 123 to the silicon-based driver substrate 20. The conductive material may cover a hole wall of the cathode through hole or fully fill the cathode through hole, which is not limited herein and may be determined according to the actual needs.

Each of the plurality of anode through holes 111 may be a straight through hole or a non-straight through hole. For example, a cross section of the anode through hole 111 in a direction perpendicular to the glass substrate 11 may be rectangular, trapezoidal, parallelogrammical, or the like. Similarly, the cathode through hole may be a straight through hole or a non-straight through hole.

In the present embodiment, the anode through hole 111 may be the straight through hole, such that a current path may be reduced, and the through hole may be formed easily. In the direction perpendicular to the glass substrate 11, the cross section of the anode through hole 111 may be in a shape of an inverted trapezoid, such that respective anode leads 13 of the plurality of anode leads may be easily attached to a hole wall of the anode through hole 111. A width of the inverted trapezoid decreases along a direction approaching the glass substrate 11.

Both the cathode through hole and the anode through holes 111 are prepared using the Through-Glass Via (TGV) technology.

To be noted that the anode through holes 111 and the cathode through hole in the present disclosure refer to original holes, instead of metallized via holes. That is, each anode through hole 111 in the present disclosure does not include any conductive material arranged in the anode through hole 111.

It should be understood that, compared to through holes in silicon material, through holes formed by the TGV may have excellent high-frequency electrical performance, have low costs, may be achieved by performing simple processes, and may be highly mechanically stable.

Compared to the related art in which the plurality of sub-pixels 12 are prepared on the silicon-based driver substrate 20 and electrically connected to the silicon-based driver substrate 20 through silicon through holes, in the present disclosure, the plurality of sub-pixel 12 are arranged on the glass substrate 11 and are bonded to the silicon-based driver substrate 20 through the glass through holes, and in this way, production costs may be reduced, and high-frequency electrical performance may be improved.

A size relationship between the cathode through hole and the anode through holes 111 may not be limited herein and may be determined according to the actual needs.

In some embodiments, in a direction parallel to the glass substrate 11, a cross section of each anode through hole 111 may be regularly or irregularly shaped, such as being circular, triangular, rhombus, rectangular, hexagonal, and so on. The shape of the cross section is not limited herein, and may be determined according to the actual needs.

In the present embodiment, in the direction parallel to the glass substrate 11, the cross section of the anode through hole 111 may be circular.

Each of the plurality of sub-pixel 12 may be an OLED. The sub-pixel 12 may include an anode 121, a light emitting layer 122, and a cathode 123 that are stacked sequentially. The anode 121 is arranged on a side surface of the glass substrate 11 away from the silicon-based driver substrate 20.

In some embodiments, the sub-pixel 12 has a size of 6 μm to 15 μm. It should be understood that the size of the sub-pixel 12 may be in other values.

In some embodiments, the cathode 123 may be one integral planar structure and may cover the plurality of insulating layers 14 and the plurality of sub-pixels 12. The plurality of sub-pixels 12 in the different colors may be a red sub-pixel R, a green sub-pixel G, and a blue sub-pixel B.

In other embodiments, the cathode 123 may not be one integral planar structure, and the plurality of sub-pixels 12 may be in other colors. The display panel 100 may include sub-pixels 12 in more colors, which are not limited herein and may be determined based on actual needs.

Each of the plurality of sub-pixels 12 may be arranged corresponding to one respective anode through hole 111 of the plurality of anode through holes 111. One anode through hole 111 of the plurality of anode through holes 111 may be arranged corresponding to one or two sub-pixels 12 of the plurality of sub-pixels. That is, every adjacent two sub-pixels of a portion of the plurality of sub-pixels 12 may share one anode through hole 111, such that the number of the plurality of anode through holes 111 may be smaller than the number of the plurality of sub-pixels 12.

In some embodiments, in the direction parallel to the glass substrate 11, the plurality of anode through holes 111 may be disposed at a side of corresponding sub-pixels 12. That is, the plurality of sub-pixels 12 are staggeredly arranged with the plurality of anode through holes 111. In this way, flatness of a film layer of the anodes 121 may be improved, and a light emitting effect of the plurality of sub-pixels 12 may be enhanced.

In some embodiments, each of the plurality of anode leads 13 may cover a portion of a hole wall of a respective anode through hole 111 of the plurality of anode through holes 111. The anode 121 of the sub-pixel 12 and the respective anode lead 13 may be formed by patterning one same conductive layer. The two anode leads 13 sharing the one anode through hole 111 may be formed by patterning different conductive layers.

That is, the anodes 121 of all of the plurality of sub-pixels 12 in the present disclosure may not be formed by patterning one conductive layer, but formed by patterning a plurality of conductive layers. Certain one anode 121 of one sub-pixel 12 and the anode lead 13 connected to the certain one anode 121 may be formed by patterning one conductive layer.

It should be noted that the adjacent two sub-pixels 12 of a portion of the plurality of sub-pixels share one anode through hole 111, however, two anodes 121 of the adjacent two sub-pixels 12 may not be connected to one anode lead 13. Instead, the two anode leads 13 of the adjacent two sub-pixels 12 are received in one anode through hole 111 and may be insulated from each other.

An end of each of the plurality of anode leads 13 may be electrically connected to the anode 121 of the respective one of the plurality of sub-pixels, and the other end of the anode lead 13 may extend through the respective anode through hole 111 to be electrically connected to the silicon-based driver substrate 20. The anode lead 13 may cover a portion of the hole wall of the respective anode through hole 111 and may not fully fill the respective anode through hole 111.

In some embodiments, the plurality of insulating layers 14 may have a plurality of pixel openings 140, and the plurality of pixel openings 140 may be arranged in one-to-one correspondence with the anodes 121 and expose the anodes 121.

The two anode leads 13 received in one anode through hole 111 may be denoted as a first anode lead 13A and a second anode lead 13B, respectively.

The plurality of insulating layers 14 may include a plurality of first insulating layers 141 and a plurality of second insulating layers 142. The plurality of first insulating layers 141 and the plurality of second insulating layers 142 may be formed by patterning different insulating material layers. In the direction perpendicular to the glass substrate 11, each of the plurality of first insulating layers 141 and a respective one of the plurality of second insulating layers 142 may be partially overlapping to each other. An overlapping region may be located between two of the plurality of sub-pixels 12. The first insulating layer 141 may cover at least the first anode lead 13A, and the second insulating layer 142 may cover at least the second anode lead 13B.

The plurality of insulating layers 14 may serve as a pixel definition layer (PDL), such that preparation of the pixel definition layer may be omitted.

The plurality of pixel openings 140 may be defined in the plurality of first insulating layers 141 or the plurality of second insulating layers 142. That is, the plurality of pixel openings 140 may be located in non-overlapping regions of the plurality of first insulating layers 141 and the plurality of second insulating layers 142.

A portion of each first insulating layer 141 may be received in the respective anode through hole 111 to cover the first anode lead 13A, and another portion of the respective first insulating layer 141 may be disposed on a side of the anode 121 away from the glass substrate 11 and may expose the anode 121 to define a position of the sub-pixel 12.

Similarly, a portion of the second insulating layer 142 may be received in the anode through hole 111 to cover the second anode lead 13B, and another portion of the second insulating layer 142 may be disposed on the side of the anode 121 away from the glass substrate 11 and may expose the anode 121 to limit the position of the sub-pixel 12.

It may be understood that the portion of the first insulating layer 141 disposed on the side of the anode 121 away from the glass substrate 11 may serve as the pixel definition layer, and the portion of the second insulating layer 142 disposed on the side of the anode 121 away from the glass substrate 11 may serve as the pixel definition layer.

In some embodiments, in the overlapping region, the second insulating layer 142 may be disposed on a side surface of the first insulating layer 141 away from the glass substrate 11, and an overlapping portion of the second insulating layer 142 may form an isolation structure 16 to isolate sub-pixels 12. In this way, preparation of the isolation structure 16 may be omitted.

That is, in the overlapping region, the second insulating layer 142 disposed on the side surface of the first insulating layer 141 away from the glass substrate 11 may protrude from the first insulating layer 141 to form the isolation structure 16. The isolation structure 16 may isolate light emitting layers 122 of two sub-pixels 12, such that pixel crosstalk may be prevented.

In other embodiments, another structure may be arranged in the overlapping region isolate the light emitting layers 122 of the sub-pixels 12, which is not limited herein and may be determined according to the actual needs.

In some embodiments, the display panel 100 may include a plurality of sub-pixel columns 124, each of the plurality of sub-pixel columns 124 may include a plurality of pixel groups 125 that are consecutively arranged. Each of the plurality of pixel groups 125 may include adjacent two sub-pixels 12, and two anode leads 13 corresponding to one pixel group 125 share one anode through hole 111. In each of the plurality of pixel groups 125, the corresponding one anode through hole 111 may be located between the two sub pixels 12 to minimize a wire length. Each of the plurality of sub-pixel columns 124 may include a plurality of sub-pixels 12 that are sequentially arranged along a predetermined direction. One sub-pixel column 124 may be a row of sub-pixels 12 or a column of sub-pixels 12.

In the present disclosure, the sub-pixel column 124 may be illustrated based on an example of a column of sub-pixels 12.

In the sub-pixel column 124, the anode through holes 111 may be located at a side of a column direction of the sub-pixels 12, such that anode through holes 111 corresponding to one column of sub-pixels 12 may be located in one straight line. In this way, a path of forming the through holes may be reduced, and a through-hole forming efficiency may be improved.

In some embodiments, the number of anode through holes 111 corresponding to one sub-pixel column 124 may be equal to the number of plurality of pixel groups 125 in one sub-pixel column 124, and that is, the number of sub-pixels 12 may be twice the number of anode through holes 111. Compared to the related art in which the number of sub-pixels 12 is equal to the number of anode through holes 111, in the present disclosure, the number of through holes to be formed may be reduced by half, and the risk of breakage of the glass substrate 11 in subsequent production processes may be reduced. Furthermore, two sub-pixels 12 may be arranged between adjacent two anode through holes 111, such that a spacing between the adjacent two anode through holes 111 may be increased, and the risk of breakage of the glass substrate 11 in the subsequent production processes may be reduced.

In other embodiments, in one sub-pixel column 124, the number of corresponding anode through holes 111 may be greater than the number of pixel groups 125. Each of a first sub-pixel 12 and a last sub-pixel 12 in the sub-pixel column 124 may be denoted as an end sub-pixel 126. At least one end sub-pixel 126 is arranged with one anode through hole 111 that is exclusively used for the end sub-pixel 126. The anode through hole 111 for the end sub-pixel 126 may be located at a side of the corresponding end sub-pixel 126 away from the pixel groups 125. That is, in the sub-pixel column 124, the first sub-pixel 12 in the column direction may be the end sub-pixel 126, and the last sub-pixel 12 in the column direction may be the end sub-pixel 126. That is, the sub-pixel column 124 may include two end sub-pixels 126. One of the two end sub-pixels 126 may be arranged with the anode through hole 111 that is exclusively for the one end sub-pixel 126; and the other one of the two end sub-pixels 126 may share the anode through hole 111 with a sub-pixel 12 adjacent to the other one end sub-pixels 126. The number of anode through holes 111 corresponding to the sub-pixel column 124 may be twice the number of pixel groups 125 in the sub-pixel column 124 adding 1. Alternatively, each of the two end sub-pixels 126 may be arranged with one anode through hole 111 exclusively, and the number of anode through holes 111 corresponding to the sub-pixel column 124 may be twice the number of pixel groups 125 in the sub-pixel column 124 adding 2.

In an embodiment, the anode through hole 111 receiving only one anode lead 13 may be disposed on the side of the corresponding one end sub-pixel 126 away from the other end sub-pixel 126. In this way, two sub-pixels 12 may be arranged between the adjacent two anode through holes 111 in the sub-pixel column 124 and separate the adjacent two anode through holes 111 apart from each other. The spacing between the adjacent two anode through holes 111 may be increased, and the risk of breakage of the glass substrate 11 in the subsequent production processes may be reduced.

It is to be noted that, for a part of the plurality of sub-pixel columns 124, the number of anode through holes 111 corresponding one sub-pixel column 124 may be equal to the number of pixel groups 125 in the one sub-pixel column 124. For another part of the plurality of sub-pixel columns 124, the number of anode through holes 111 corresponding one sub-pixel column 124 may be greater than the number of pixel groups 125 in the one sub-pixel column 124. Alternatively, for each of the plurality of sub-pixel columns 124, the number of anode through holes 111 corresponding one sub-pixel column 124 may be equal to the number of pixel groups 125 in the one sub-pixel column 124. Alternatively, for each of the plurality of sub-pixel columns 124, the number of anode through holes 111 corresponding one sub-pixel column 124 may be greater than the number of pixel groups 125 in the one sub-pixel column 124. The plurality of sub-pixel columns 124 may have different numbers or the same number of pixel groups 125. The plurality of sub-pixel columns 124 may have different numbers or the same number of sub-pixels 12. The numbers may be in relation to arrangement of the plurality of sub-pixels 12, which is not limited herein, and may be determined according to the actual needs.

In the present embodiment, for each sub-pixel column 124, the number of sub-pixels 12 in one sub-pixel column 124 may be a sum of the number of anode through holes 111 corresponding the one sub-pixel column 124 and the number of pixel groups 125 in the one sub-pixel column 124.

In the present embodiment, for each sub-pixel column 124, the number of anode through holes 111 corresponding to one sub-pixel column 124 may be equal to the number of pixel groups 125 in the one sub-pixel column 124.

In some embodiments, three sub-pixels 12 of different colors may form one pixel unit 120, and a plurality of pixel units 120 may be arranged in an array. An extension direction of the sub-pixel column 124 may be a column direction of the plurality of pixel units 120.

In each of the plurality of pixel units 120, two of the three sub-pixels 12 may form a first pixel row 12A along a first direction D1, and the rest one of the three sub-pixels 12 is extending along the first direction D1 to form a second pixel row 12B. The first pixel row 12A and the second pixel row 12B may be arranged in a predetermined direction, and the predetermined direction may be either the first direction D1 or a second direction D2. The first direction D1 may be the column direction of the plurality of pixel units 120, and the second direction D2 may be a row direction of the plurality of pixel units 120. When the predetermined direction is the first direction D1, each column of pixel units 120 may include one sub-pixel column 124. When the predetermined direction is the second direction D2, each column of pixel units 120 may include two sub-pixel columns 124.

In some embodiments, the predetermined direction may be the second direction D2, and each column of pixel units 120 may include two sub-pixel columns 124. In the first direction D1, adjacent two pixel units 120 may be repetitively arranged or may be arranged in mirror to each other or arranged centro-symmetrically; and/or in the second direction D2, adjacent two pixel units 120 may be repetitively arranged or may be arranged in mirror to each other.

In an embodiment, as shown in FIG. 2, in each of the plurality of pixel units 120, the red sub-pixel R and the green sub-pixel G may be sequentially arranged in the first pixel row 12A along the first direction D1, and the blue sub-pixel B may be extending along the first direction D1 to form the second pixel row 12B. In the direction parallel to the glass substrate 11, each of the plurality of sub-pixel 12 may be rectangular, and the pixel unit 120 may be rectangular. In the first direction D1, a left side of the red sub-pixel R may be aligned with a left side of the green sub-pixel G, and a right side of the red sub-pixel R may be aligned with a right side of the green sub-pixel G. In the second direction D2, a side of the red sub-pixel R away from the green sub-pixel G may be aligned with a side of the blue sub-pixel B, and a side of the green sub-pixel G away from the red sub-pixel R may be aligned with another other side of the blue sub-pixel B.

In other embodiments, the sub-pixel 12 may be trapezoidal, triangular, or parallelogrammical, which is not limited herein and may be determined according to the actual needs. The pixel unit 120 may be parallelogrammical.

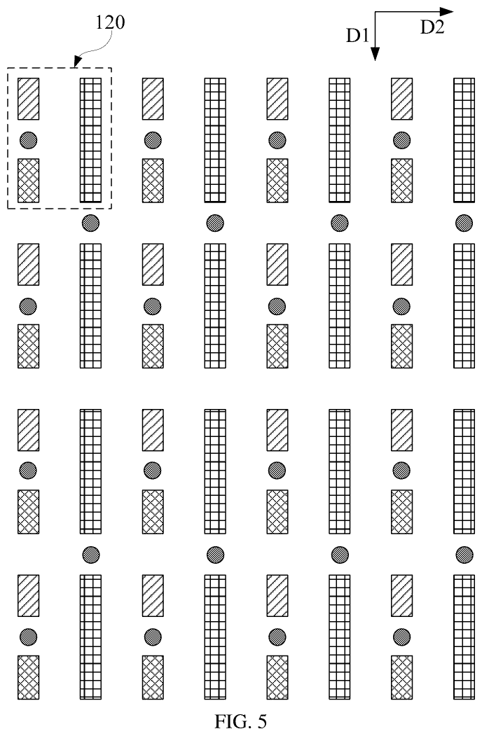

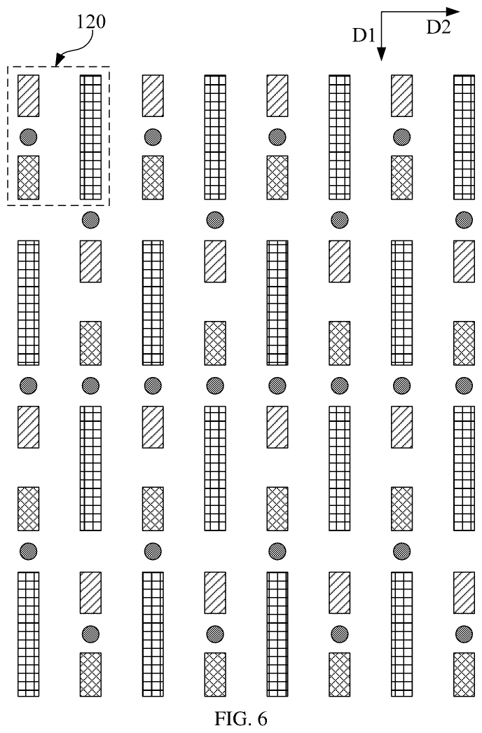

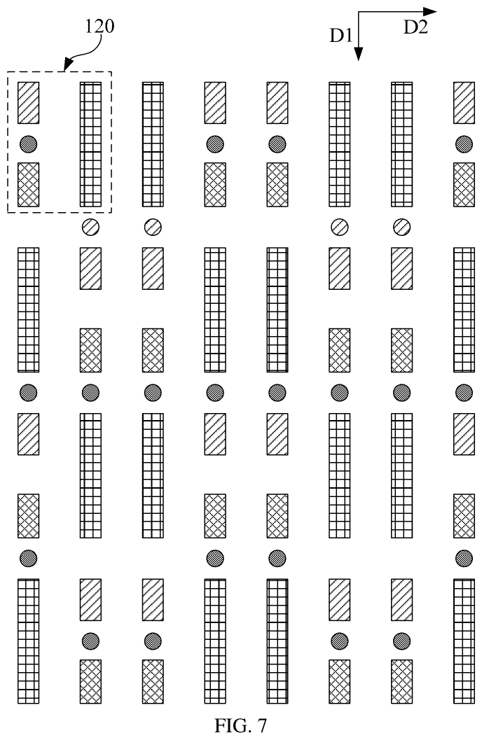

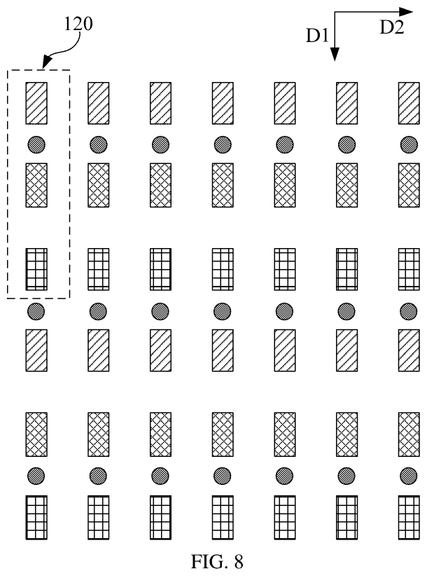

As shown in FIGS. 2 to 8, FIG. 4 is a structural schematic view of the display panel according to a second embodiment of the present disclosure; FIG. 5 is a structural schematic view of the display panel according to a third embodiment of the present disclosure; FIG. 6 is a structural schematic view of the display panel according to a fourth embodiment of the present disclosure; FIG. 7 is a structural schematic view of the display panel according to a fifth embodiment of the present disclosure; FIG. 8 is a structural schematic view of the display panel according to a sixth embodiment of the present disclosure.

In an embodiment, as shown in FIGS. 2 and 4, in the first direction D1, every adjacent two pixel units 120 may be centro-symmetrically arranged with each other. In the second direction D2, every adjacent two pixel units 120 may be arranged in mirror to each other. In each column of pixel units 120, the number of anode through holes 111 corresponding to one column of sub-pixels 12 may be twice the number of pixel groups 125 in one column adding two; and the number of corresponding anode through holes 111 in another one column of sub-pixels 12 may be equal to the number of pixel groups 125 in the another one column. In this way, the risk of breakage of the glass substrate 11 in subsequent production processes may be effectively reduced.

In an embodiment, as shown in FIG. 5, the plurality of pixel units 120 may be repetitively arranged in the first direction D1 and repetitively arranged in the second direction D2. Alternatively, as shown in FIG. 6, in the first direction D1, every adjacent two pixel units 120 may be arranged centro-symmetrically to each other; and the pixel units 120 may be repetitively arranged in the second direction D2. in the first direction D1, every adjacent two pixel units 120 may be arranged centro-symmetrically to each other; and in the second direction D2, every adjacent two pixel units 120 may be arranged in mirror to each other. Compared to the related art in which one sub-pixel 12 corresponds to one anode through hole 111 and the number of sub-pixels 12 is equal to the number of anode through holes 111, in the present disclosure, the number of anode through holes 111 corresponding to each column of sub-pixels 12 may be equal to the number of pixel groups 125 in the corresponding one column, i.e., the number of sub-pixels 12 in each column of sub-pixels 12 may be twice the number of anode through holes 111 corresponding to one column. Therefore, in the present disclosure, the number of anode through holes 111 may be reduced by one half, and the risk of breakage of the glass substrate 11 in the subsequent production processes may be effectively reduced.

In an embodiment, as shown in FIG. 8, in each pixel unit 120, the first pixel row 12A and the second pixel row 12B are arranged side by side, along the first direction D1. A plurality of pixel units 120 are sequentially repetitively arranged in the first direction D1 and sequentially repetitively arranged in the second direction D2. Compared to the related art in which one sub-pixel 12 corresponds to one anode through hole 111 and the number of sub-pixels 12 is equal to the number of anode through holes 111, in the present disclosure, the number of anode through holes 111 corresponding to each column of sub-pixels 12 may be equal to the number of pixel groups 125 in the corresponding one column. In this way, the number of anode through holes 111 may be reduced by one half, and the risk of breakage of the glass substrate 11 in the subsequent production processes may be effectively reduced.

The light emitting carrier board 10 may further include an encapsulation layer 15, the encapsulation layer 15 may be disposed on a side of the plurality of sub-pixels 12 away from the glass substrate 11. A material of the encapsulation layer 15 may not be limited herein, and may be determined according to actual needs.

In some embodiments, the silicon-based driver substrate 20 may further include a protection layer 23, the protection layer 23 may be arranged on a side of the driver circuit layer 22 away from the silicon substrate 21; and/or, the light emitting carrier board 10 may further include a protection layer 23, the protection layer 23 may be arranged on a side of the glass substrate 11 away from the plurality of sub-pixels 12.

In the present embodiment, the silicon-based driver substrate 20 may further include the protection layer 23. The protection layer 23 may be arranged on the side of the driver circuit layer 22 away from the silicon substrate 21.

The silicon-based driver substrate 20 may have anode drive electrodes 24. In the direction perpendicular to the glass substrate 11, each anode drive electrode 24 may extend through the protection layer 23 and may electrically connect the respective anode lead 13 to the driver circuit layer 22. The silicon-based driver substrate 20 may further include a cathode driver electrode (not shown) configured to electrically connect the conductive material in the cathode through hole to the driver circuit layer 22.

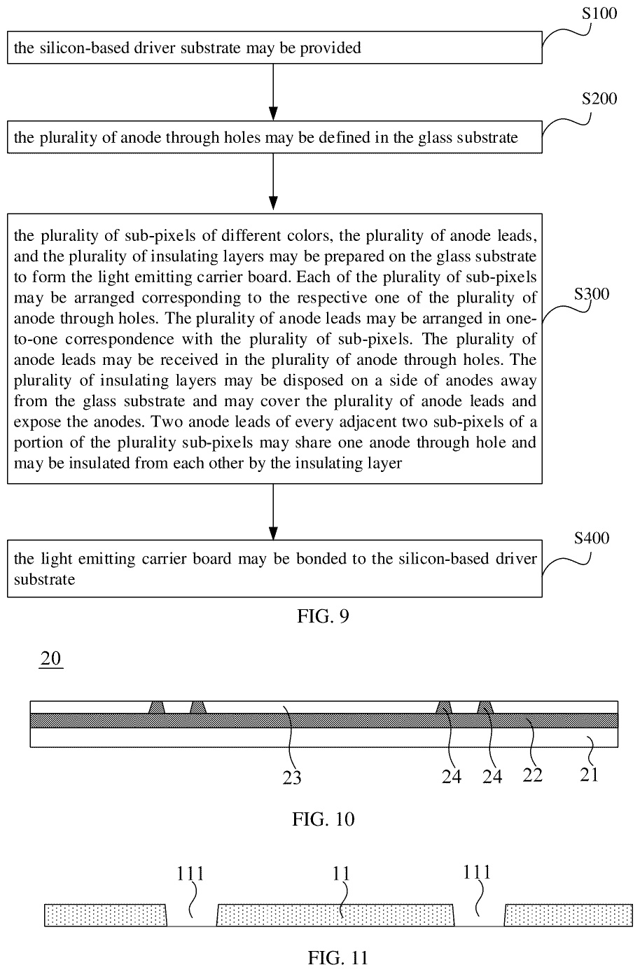

As shown in FIG. 2, FIG. 3, and FIGS. 9 to 11, FIG. 9 is a flow chart of a method of manufacturing the display panel according to an embodiment of the present disclosure; FIG. 10 is a structural schematic view of a structure corresponding to the operation S100 of the method shown in FIG. 9; and FIG. 11 is a structural schematic view of a structure corresponding to the operation S200 of the method shown in FIG. 9.

The present disclosure provides a method of manufacturing the display panel 100 as described in the above.

The method of manufacturing the display panel may include following operations.

In an operation S100, the silicon-based driver substrate may be provided.

Specifically, the silicon-based driver substrate 20 may be provided, and a structure of the silicon-based driver substrate 20 may be referred to the above description and will not be repeated herein.

In an operation S200, the plurality of anode through holes may be defined in the glass substrate.

Specifically, a plurality of holes may be formed in the glass substrate 11 to form the plurality of anode through holes 111.

It should be understood that the holes formed in the glass substrate 11 may further form the cathode through hole.

In an operation S300, the plurality of sub-pixels of different colors, the plurality of anode leads, and the plurality of insulating layers may be prepared on the glass substrate to form the light emitting carrier board. Each of the plurality of sub-pixels may be arranged corresponding to the respective one of the plurality of anode through holes. The plurality of anode leads may be arranged in one-to-one correspondence with the plurality of sub-pixels. The plurality of anode leads may be received in the plurality of anode through holes. The plurality of insulating layers may be disposed on a side of anodes away from the glass substrate and may cover the plurality of anode leads and expose the anodes. Two anode leads of every adjacent two sub-pixels of a portion of the plurality sub-pixels may share one anode through hole and may be insulated from each other by the insulating layer.

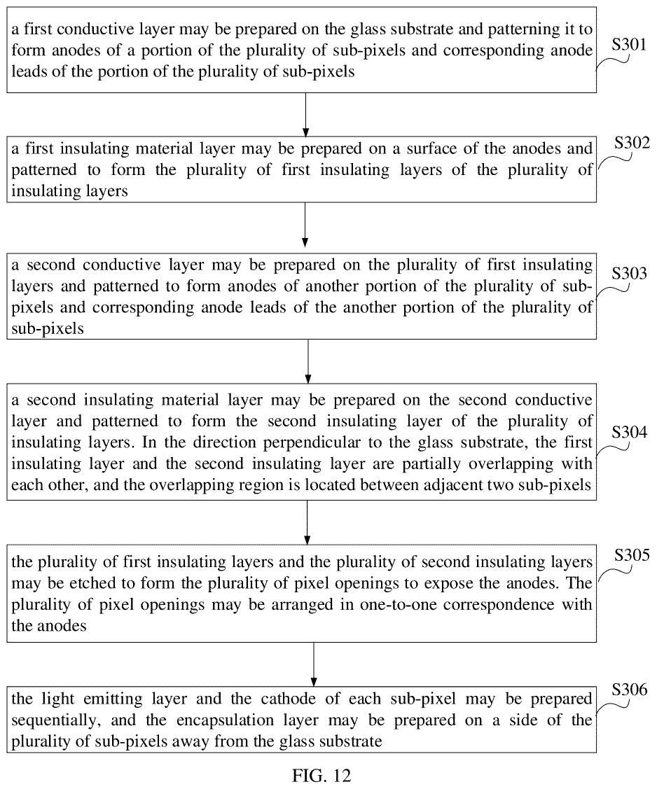

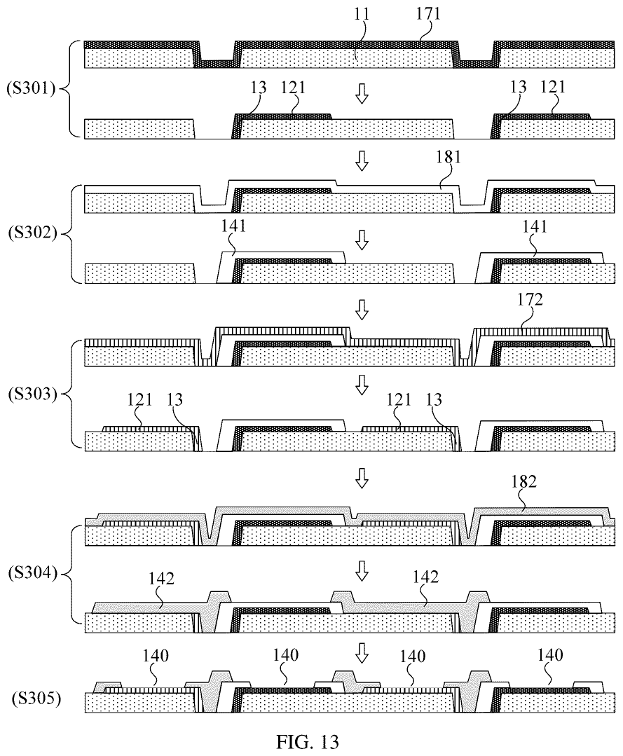

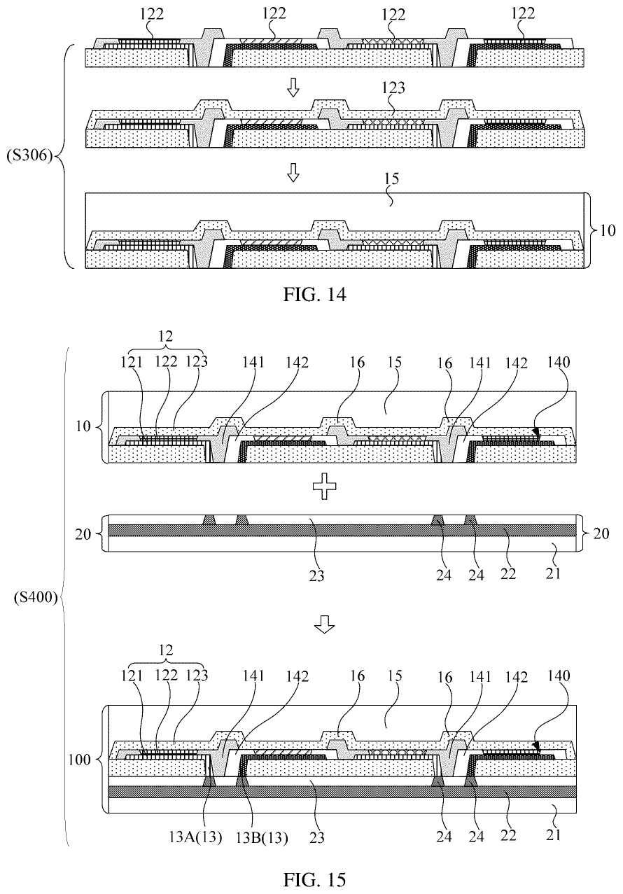

As shown in FIGS. 2 to 15, FIG. 12 is a flow chart of the operation S300 of the method shown in FIG. 9; FIG. 13 is a structural schematic view of structures corresponding to operations S301 to S305 of the operation shown in FIG. 12; FIG. 14 is a structural schematic view of a structure corresponding to the operation S306 of the operation shown in FIG. 12; and FIG. 15 is a structural schematic view of a structure corresponding to the operation S400 of the method shown in FIG. 9.

In some embodiments, the operation S300 where the plurality of sub-pixels of different colors, the plurality of anode leads, and the plurality of insulating layers are prepared on the glass substrate to form the light emitting carrier board may include following operations.

In an operation Step S301, a first conductive layer may be prepared on the glass substrate and patterning it to form anodes of a portion of the plurality of sub-pixels and corresponding anode leads of the portion of the plurality of sub-pixels.

Specifically, the first conductive layer 171 may be deposited on the glass substrate 11, and exposure, development, and etching may be performed to form a desired pattern to form the anodes 121 of the portion of the plurality of sub-pixels 12 and the corresponding anode leads 13 of the portion of the plurality of sub-pixels 12.

A material and a thickness of the first conductive layer 171 may not be limited herein, and may be determined according to actual needs.

In an operation Step S302, a first insulating material layer may be prepared on a surface of the anodes and patterned to form the plurality of first insulating layers of the plurality of insulating layers.

Specifically, the first insulating material layer 181 may be deposited on the first conductive layer 171, the first insulating material layer 181 may cover the glass substrate 11. After exposure, development, and etching, a desired pattern may be formed to form the plurality of first insulating layers 141, and the plurality of first insulating layers 141 may cover a portion of the first conductive layer 171 retained on the glass substrate 11 after patterning.

A material of the first insulating material layer 181 may be the same as or different from a material of the pixel definition layer. The material and a thickness of the first insulating material layer 181 may not be limited herein, and may be determined according to actual needs.

In an operation Step S303, a second conductive layer may be prepared on the plurality of first insulating layers and patterned to form anodes of another portion of the plurality of sub-pixels and corresponding anode leads of the another portion of the plurality of sub-pixels.

Specifically, the second conductive layer 172 may be deposited on the glass substrate 11, the second conductive layer 172 may cover the plurality of first insulating layers 141 and the glass substrate 11. Exposure, development, and etching may be performed to form a desired pattern to form the anodes 121 of the another portion of the sub-pixels 12 and the corresponding anode leads 13. A material and a thickness of the second conductive layer 172 may not be limited herein, and may be determined according to actual needs.

In the present embodiment, the thickness of the first conductive layer 171 may be the same as the thickness of the second conductive layer 172.

In an operation Step S304, a second insulating material layer may be prepared on the second conductive layer and patterned to form the second insulating layer of the plurality of insulating layers. In the direction perpendicular to the glass substrate, the first insulating layer and the second insulating layer are partially overlapping with each other, and the overlapping region is located between adjacent two sub-pixels.

Specifically, the second insulating material layer 182 may be deposited on the second conductive layer 172. After exposure, development, and etching, a desired pattern may be formed to form the second insulating layer 142. The second insulating layer 142 may cover a portion of the second conductive layer 172 that is retained on the glass substrate 11 after patterning. In a region between adjacent two sub-pixels 12, the respective second insulating layer 142 and the respective first insulating layer 141 are overlapping with each other.

A positional relationship of the first insulating layer 141 and the second insulating layer 142 may be referred to the above description and will not be repeated herein.

The material and the thickness of the first insulating material layer 181 may not be limited herein, and may be determined according to actual needs.

In the present embodiment, the thickness of the first insulating material layer 181 may be the same as the thickness of the second insulating material layer 182.

In an operation S305, the plurality of first insulating layers and the plurality of second insulating layers may be etched to form the plurality of pixel openings to expose the anodes. The plurality of pixel openings may be arranged in one-to-one correspondence with the anodes.

Specifically, the first insulating layer 141 and the second insulating layer 142 may be etched to form the plurality of pixel openings 140 to expose the anodes 121. The plurality of pixel openings 140 may be arranged in one-to-one correspondence with the anodes 121.

In some implementations, the operation S300 where the plurality of sub-pixels of different colors, the plurality of anode leads, and the plurality of insulating layers are prepared on the glass substrate to form the light emitting carrier board may further include following operations.

In an operation Step S306, the light emitting layer and the cathode of each sub-pixel may be prepared sequentially, and the encapsulation layer may be prepared on a side of the plurality of sub-pixels away from the glass substrate.

Specifically, the light emitting layer 122 of the sub-pixel 12 may be prepared by performing a fine metal masking (FMM) process, and the cathode 123 and the encapsulation layer 15 may be sequentially prepared on the light emitting layer 122.

To be noted that light emitting layers 122 of the plurality of sub-pixels 12 in the different colors may be prepared using different organic materials.

In an operation S400, the light emitting carrier board may be bonded to the silicon-based driver substrate.

Specifically, the light emitting carrier board 10 may be aligned and bonded to the silicon-based driver substrate 20 to form the display panel 100.

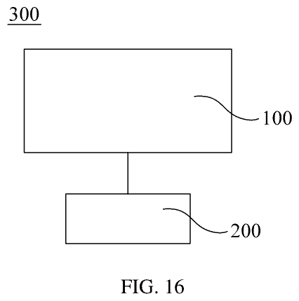

As shown in FIG. 16, FIG. 16 is a structural schematic view of a display apparatus according to an embodiment of the present disclosure.

The present disclosure provides a display apparatus. The display apparatus 300 may include a motherboard 200 and the display panel 100 as described above. The display device 300 of the present embodiment may be an AMOLED.

The motherboard 200 may be electrically connected to the display panel 100, and the motherboard 200 may be configured to transmit various desired signals to the display panel 100 to control the display panel 100 to display images. For example, the transmitted signals may be signals required by the driver circuit layer and may include a clock signal (CK), a low potential signal (Vss), a supply voltage signal (VDD), and a data signal.

In the above embodiments, description of each embodiment has its own focus, and parts that are not detailed in one embodiment may be referred to the relevant descriptions of other embodiments.

The above is only an implementation of the present disclosure, and is not intended to limit the scope of the present disclosure. Any equivalent structure or equivalent process transformation performed based on the contents of the specification and the accompanying drawings of the present disclosure, applied directly or indirectly in other related technical fields, shall be equivalently included in the scope of the present disclosure.

What is claimed is:

1. A display panel, comprising:
a silicon-based driver substrate;
a light emitting carrier board, bonded and connected to the silicon-based driver substrate; wherein the light emitting carrier board comprises:
a glass substrate, defining a plurality of anode through holes;
a plurality of sub-pixels of different colors, arranged on a surface of the glass substrate away from the silicon-based driver substrate; wherein each of the plurality of sub-pixels is arranged corresponding to a respective one of the plurality of anode through holes;
a plurality of anode leads, arranged in one-to-one correspondence with the plurality of sub-pixels; wherein the plurality of anode leads are arranged in the plurality of anode through holes to connect anodes of the plurality of sub-pixels to the silicon-based driver substrate;
a plurality of insulating layers, arranged on a side of the anodes away from the glass substrate and covering the plurality of anode leads and exposing the anodes;
wherein two anode leads of the plurality of anode leads corresponding to every adjacent two sub-pixels of a portion of the plurality of sub-pixels share a respective one of the plurality of anode through holes and are insulated from each other by a respective one of the plurality of insulating layers.

2. The display panel according to claim 1, wherein, each of the plurality of anode leads covers a portion of a hole wall of the respective anode through hole; an anode of each of the plurality of sub-pixels and a respective one of the plurality of anode leads are formed by patterning one conductive layer; and the two anode leads sharing the one anode through hole are formed by patterning different conductive layers.

3. The display panel according to claim 2, wherein the plurality of insulating layers has a plurality of pixel openings, the plurality of pixel openings are in one-to-one correspondence with the anodes and expose the anodes;
the two anode leads sharing the one anode through hole are denoted as a first anode lead and a second anode lead, respectively;
the plurality of insulating layers comprises a plurality of first insulating layers and a plurality of second insulating layers; the plurality of first insulating layers and the plurality of second insulating layers are formed by patterning different insulating material layers; in a direction perpendicular to the glass substrate, each of the plurality of first insulating layers is partially overlapping with a respective one the plurality of second insulating layers to form an overlapping region, and the overlapping region is disposed between adjacent two sub-pixels of the plurality of sub-pixels;
at least the first anode lead is covered by a respective one the plurality of first insulating layers, and at least the second anode lead is covered by a respective one the plurality of second insulating layers.

4. The display panel according to claim 3, wherein in the overlapping region, the respective second insulating layer is disposed on a side surface of the respective first insulating layer away from the glass substrate, and a portion of the respective second insulating layer of the overlapping region serves an isolation structure to isolate the adjacent two sub-pixels.

5. The display panel according to claim 2, wherein the display panel comprises a plurality of sub-pixel columns, each of the plurality of sub-pixel columns comprises a plurality of pixel groups that are consecutively arranged; each of the plurality of pixel groups comprises adjacent two sub-pixels of the plurality of sub-pixels; two anode leads corresponding to each of the plurality of pixel groups share the one anode through hole; in each of the plurality of pixel groups, the one anode through hole is located between the adjacent two sub-pixels.

6. The display panel according to claim 5, wherein in at least a portion of the plurality of sub-pixel columns, the number of anode through holes corresponding to each column of the at least a portion of the plurality of sub-pixel columns is equal to the number of pixel groups in one column.

7. The display panel according to claim 5, wherein in at least a portion of the plurality of sub-pixel columns, the number of anode through holes corresponding to each column of the at least a portion of the plurality of sub-pixel columns is greater than the number of pixel groups in one column; a first sub-pixel and a last sub-pixel in each column of the plurality of sub-pixel columns are denoted as two end sub-pixels; at least one of the two end sub-pixels is arranged with an exclusive one anode through hole.

8. The display panel according to claim 5, wherein, in at least a portion of the plurality of sub-pixel columns, the number of anode through holes corresponding to each column of the at least a portion of the plurality of sub-pixel columns is equal to the number of pixel groups in one column adding 1 or 2.

9. The display panel according to claim 2, wherein each of the plurality of sub-pixels comprises the anode, a light emitting layer and a cathode that are stacked sequentially; the cathode is configured as a one integral planar structure and covers the plurality of insulating layers and the plurality of sub-pixels;
the plurality of sub-pixels in the different colors are a red sub-pixel, a green sub-pixel and a blue sub-pixel.

10. A display apparatus, comprising a motherboard and a display panel electrically connected to the motherboard; wherein the display panel, comprises:
a silicon-based driver substrate;
a light emitting carrier board, bonded and connected to the silicon-based driver substrate; wherein the light emitting carrier board comprises:
a glass substrate, defining a plurality of anode through holes;
a plurality of sub-pixels of different colors, arranged on a surface of the glass substrate away from the silicon-based driver substrate; wherein each of the plurality of sub-pixels is arranged corresponding to a respective one of the plurality of anode through holes;
a plurality of anode leads, arranged in one-to-one correspondence with the plurality of sub-pixels; wherein the plurality of anode leads are arranged in the plurality of anode through holes to connect anodes of the plurality of sub-pixels to the silicon-based driver substrate;
a plurality of insulating layers, arranged on a side of the anodes away from the glass substrate and covering the plurality of anode leads and exposing the anodes;
wherein two anode leads of the plurality of anode leads corresponding to every adjacent two sub-pixels of a portion of the plurality of sub-pixels share a respective one of the plurality of anode through holes and are insulated from each other by a respective one of the plurality of insulating layers.

11. The display apparatus according to claim 10, wherein, each of the plurality of anode leads covers a portion of a hole wall of the respective anode through hole; an anode of each of the plurality of sub-pixels and a respective one of the plurality of anode leads are formed by patterning one conductive layer; and the two anode leads sharing the one anode through hole are formed by patterning different conductive layers.

12. The display apparatus according to claim 11, wherein the plurality of insulating layers has a plurality of pixel openings, the plurality of pixel openings are in one-to-one correspondence with the anodes and expose the anodes;
the two anode leads sharing the one anode through hole are denoted as a first anode lead and a second anode lead, respectively;
the plurality of insulating layers comprises a plurality of first insulating layers and a plurality of second insulating layers; the plurality of first insulating layers and the plurality of second insulating layers are formed by patterning different insulating material layers; in a direction perpendicular to the glass substrate, each of the plurality of first insulating layers is partially overlapping with a respective one the plurality of second insulating layers to form an overlapping region, and the overlapping region is disposed between adjacent two sub-pixels of the plurality of sub-pixels;
at least the first anode lead is covered by a respective one the plurality of first insulating layers, and at least the second anode lead is covered by a respective one the plurality of second insulating layers.

13. The display apparatus according to claim 12, wherein in the overlapping region, the respective second insulating layer is disposed on a side surface of the respective first insulating layer away from the glass substrate, and a portion of the respective second insulating layer of the overlapping region serves an isolation structure to isolate the adjacent two sub-pixels.

14. The display apparatus according to claim 11, wherein the display panel comprises a plurality of sub-pixel columns, each of the plurality of sub-pixel columns comprises a plurality of pixel groups that are consecutively arranged; each of the plurality of pixel groups comprises adjacent two sub-pixels of the plurality of sub-pixels; two anode leads corresponding to each of the plurality of pixel groups share the one anode through hole; in each of the plurality of pixel groups, the one anode through hole is located between the adjacent two sub-pixels.

15. The display apparatus according to claim 14, wherein in at least a portion of the plurality of sub-pixel columns, the number of anode through holes corresponding to each column of the at least a portion of the plurality of sub-pixel columns is equal to the number of pixel groups in one column.

16. The display apparatus according to claim 14, wherein in at least a portion of the plurality of sub-pixel columns, the number of anode through holes corresponding to each column of the at least a portion of the plurality of sub-pixel columns is greater than the number of pixel groups in one column; a first sub-pixel and a last sub-pixel in each column of the plurality of sub-pixel columns are denoted as two end sub-pixels; at least one of the two end sub-pixels is arranged with an exclusive one anode through hole.

17. The display apparatus according to claim 14, wherein, in at least a portion of the plurality of sub-pixel columns, the number of anode through holes corresponding to each column of the at least a portion of the plurality of sub-pixel columns is equal to the number of pixel groups in one column adding 1 or 2.

18. The display apparatus according to claim 12, wherein each of the plurality of sub-pixels comprises the anode, a light emitting layer and a cathode that are stacked sequentially; the cathode is configured as a one integral planar structure and covers the plurality of insulating layers and the plurality of sub-pixels;
the plurality of sub-pixels in the different colors are a red sub-pixel, a green sub-pixel and a blue sub-pixel.

19. A method of manufacturing the display panel according to claim 1, the method comprising:
providing the silicon-based driver substrate;
defining the plurality of anode through holes in the glass substrate;
preparing the plurality of sub-pixels of different colors, the plurality of anode leads and the plurality of insulating layers on the glass substrate to form the light emitting carrier board; wherein each of the plurality of sub-pixels is arranged corresponding to the respective one of the plurality of anode through holes; the plurality of anode leads are arranged in one-to-one correspondence with the plurality of sub-pixels; the plurality of anode leads are arranged in the plurality of anode through holes; the plurality of insulating layers are arranged on the side of the anodes away from the glass substrate and cover the plurality of anode leads and expose the anodes; wherein two anode leads of the plurality of anode leads corresponding to every adjacent two sub-pixels of the portion of the plurality of sub-pixels share the respective one of the plurality of anode through holes and are insulated from each other by the respective one of the plurality of insulating layers;
bonding the light emitting carrier board to the silicon-based driver substrate.

20. The method according to claim 19, wherein the preparing the plurality of sub-pixels of different colors, the plurality of anode leads and the plurality of insulating layers on the glass substrate to form the light emitting carrier board, comprises:
preparing a first conductive layer on the glass substrate and patterning the first conductive layer to form anodes of a portion of the plurality of sub-pixels and a portion of the plurality of anode leads corresponding to the portion of the plurality of sub-pixels;
preparing a first insulating material layer on a surface of the anodes and patterning the first insulating material layer to form the plurality of first insulating layers of the plurality of insulating layers;
preparing a second conductive layer on the plurality of first insulating layers and patterning the second conductive layer to form anodes of another portion of the plurality of sub-pixels and another portion of the plurality of anode leads corresponding to the another portion of the plurality of sub-pixels;
preparing a second insulating material layer on the second conductive layer and patterning the second insulating material layer to form the plurality of second insulating layers of the plurality of insulating layers; wherein, in a direction perpendicular to the glass substrate,
each of the plurality of first insulating layers and a respective one of the plurality of second insulating layers are partially overlapped with each other to form an overlapping portion, and the overlapping portion is disposed between adjacent two sub-pixels of the plurality of sub-pixels; and
etching the plurality of first insulating layers and the plurality of second insulating layers to form a plurality of pixel openings expose the anodes, wherein the plurality of pixel openings are in one-to-one correspondence with the anodes.
